(19) United States
(12) Patent Application Publication
(10) Pub. No.: US 2025/0128435 A1
(43) Pub. Date: Apr. 24, 2025

(54) THIN WAFER TRANSFER METHOD

(71) Applicant: ACM RESEARCH (SHANGHAI), INC., Shanghai (CN)

(72) Inventors: Zhaoming Zhong, Shanghai (CN); Xideng He, Shanghai (CN); Shaomin Min, Shanghai (CN); Xin Liu, Shanghai (CN); Shengping Lu, Shanghai (CN); Wei Zhang, Shanghai (CN); Hui Wang, Shanghai (CN)

(73) Assignee: ACM RESEARCH (SHANGHAI), INC., Shanghai (CN)

(21) Appl. No.: 18/724,524

(22) PCT Filed: Nov. 24, 2022
(86) PCT No.: PCT/CN2022/134120

§ 371 Date: Jul. 1, 2024

(30) Foreign Application Priority Data
Dec. 30, 2021 (CN) 202111651982.7

(51) Int. Cl. B25J 15/06; G05D 7/06; H01L 21/683

(52) U.S. Cl. CPC B25J 15/0625; G05D 7/0623; H01L 21/6838

(57) ABSTRACT

The present invention discloses a transfer method of thin wafer. For thin wafers with different thicknesses, in different transfer stages, a Bernoulli manipulator uses different gas flow rates, so that the problem of chipping of wafers during transfer is solved. Specifically, in a process of moving a wafer out of a wafer cassette, a Bernoulli manipulator uses a small gas flow rate, so as to reduce the suction force on the wafer and weaken warping deformation of the wafer, thereby reducing the risk of cracking or chipping in the process of moving the wafer out of the wafer cassette; after the wafer is moved out of the wafer cassette and in a process of transferring same to a processing chamber, the Bernoulli manipulator uses a large gas flow rate, so as to increase the suction force on the wafer, thereby ensuring the wafer can be stably suctioned on the Bernoulli manipulator during transfer, and avoiding wafer slipping.

### BACKGROUND OF THE INVENTION

### Field of the Invention

The application relates to the technical field of semiconductor manufacturing, more particular to a transfer method of thin wafer.

### The Related Art

With increasing complexity and integration of chip, heat dissipation has become a key factor affecting the performance and life of the chip. Thin wafer is more conducive to heat dissipation, however, thin wafer easily chips or cracks because thin wafer has large warpage.

At present, the Bernoulli manipulator is usually used to transfer the wafer, and the corresponding gas flow is provided to the Bernoulli manipulator according to the thickness of the wafer, so that the Bernoulli manipulator can stably absorb the wafer. However, in actual operation, the wafer often chips or cracks in the process of moving out of the wafer cassette.

### SUMMARY

The purpose of the application is to provide a transfer method of thin wafer, which can reduce the risk of chipping of thin wafer during transfer, especially in the process of moving from the wafer cassette.

In order to achieve the above purpose, a transfer method of thin wafer provided by the invention is applied to a Bernoulli manipulator to transfer wafers between a wafer cassette and a processing chamber. The Bernoulli manipulator is equipped with a gas path for supplying gas to the Bernoulli manipulator. The method includes the following steps:
identifying the thickness of the wafers in the wafer cassette;
obtaining gas flow parameters matched with the wafers' thickness, each gas flow parameter including two gas flow rates as a first gas flow rate and a second gas flow rate, the first gas flow rate being lower than the second gas flow rate, the first gas flow rate being the gas flow rate provided to the Bernoulli manipulator by the gas path in the process of moving the wafer from the wafer cassette, and the second gas flow rate being the gas flow rate provided to the Bernoulli manipulator by the gas path after the wafer moved from the wafer cassette and transferred to the processing chamber;
providing the gas with the first gas flow rate matching the thickness of the transferred wafer to the Bernoulli manipulator through the gas path, the Bernoulli manipulator moving the wafer out of the wafer cassette at the first gas flow rate;
then, providing the gas with the second gas flow rate matching the thickness of the transferred wafer to the Bernoulli manipulator through the gas path, the Bernoulli manipulator transferring the wafer to the processing chamber at the second flow rate.

The present invention discloses a transfer method of thin wafer. For thin wafers with different thicknesses, in different transfer stages, the Bernoulli manipulator uses different gas flow rates, so that the problem of chipping of wafers during transfer is solved. Specifically, in a process of moving a wafer out of a wafer cassette, a Bernoulli manipulator uses a small gas flow rate, so as to reduce the suction force on the wafer and weaken warping deformation of the wafer, thereby reducing the risk of cracking or chipping in the process of moving the wafer out of the wafer cassette; after the wafer is moved out of the wafer cassette and in a process of being transferred to a processing chamber, the Bernoulli manipulator uses a large gas flow rate, so as to increase the suction force on the wafer, thereby ensuring the wafer can be stably suctioned on the Bernoulli manipulator during transfer, and avoiding wafer slipping.

### BRIEF DESCRIPTION OF THE DRAWINGS

FIG. 1(a) and FIG. 1(b) illustrate the causes of chipping generated in the process of Bernoulli manipulator moving wafers from the wafer cassette;

FIG. 2 shows a flowchart of a transfer method of thin wafer according to an embodiment of the present invention;

Table 1 lists the gas flow parameters corresponding to some wafer thickness;

FIG. 3 shows a gas path configured by Bernoulli manipulator according to an embodiment of the present invention;

FIG. 4 shows a gas path configured by Bernoulli manipulator according to another embodiment of the present invention;

FIG. 5 shows a gas path configured by Bernoulli manipulator according to another embodiment of the present invention;

### DETAILED DESCRIPTION OF EMBODIMENTS

In order to explain the technical content, structural features, achieved goals and effects of the present application in detail, the following examples will be described in detail with the drawings.

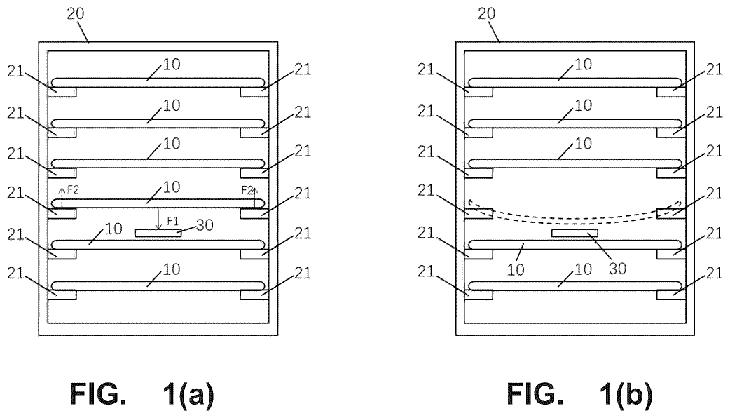

The thickness of thin wafer usually be 50-400 μm, which has low rigidity and is prone to deflection. According to the experiment, when using a Bernoulli manipulator to transfer a thin wafer, especially in the process of moving the wafer from the wafer cassette, chipping problems occur frequently. Research finding that Bernoulli manipulator adopts constant gas flow rate Q₀ in the whole process of transferring the wafer from the wafer cassette to the processing chamber, the gas flow rate Q₀ can ensure that Bernoulli manipulator provides sufficient suction force to the wafer so that the wafer is stably suctioned to the Bernoulli manipulator. Preferably, the wafer is stably suctioned to the Bernoulli manipulator in a non-contact manner. However, since the edge of the wafer 10 is horizontally supported by the support component 21 of the wafer cassette 20, as shown in FIG. 1(a). When the Bernoulli manipulator 30 sucks the wafer 10 from below the wafer 10 with the gas flow rate Q₀, the Bernoulli manipulator 30 exerts a large downward suction force F1 to the wafer 10, at the same time, the support component 21 of the wafer cassette 20 exerts an upward supporting force F2 to the wafer 10. Under the action of two forces (the suction force and the supporting force) in opposite direction, it will cause large warping deformation for the thin wafer with low rigidity, as shown in FIG. 1(b), and then cause chips or cracks.

Based on the above findings, in the present invention, the Bernoulli manipulator adopts different gas flow rates for the different transfer stages of the thin wafer. Concretely, in the process of moving the wafer out of the wafer cassette, the Bernoulli manipulator adopts a smaller gas flow rate, which reduces the suction force on the wafer and weakens the warping deformation of the wafer, thus reducing the risk of cracking or chipping in the process of moving the wafer out of the wafer cassette. After the wafer is moved from the wafer cassette, Bernoulli manipulator adopts a large gas flow rate to increase the suction force to the wafer in the process of transferring the wafer from the wafer cassette to the processing chamber, so as to ensure that the wafer can be stably adsorbed on Bernoulli manipulator during the transfer process to avoid sliding.

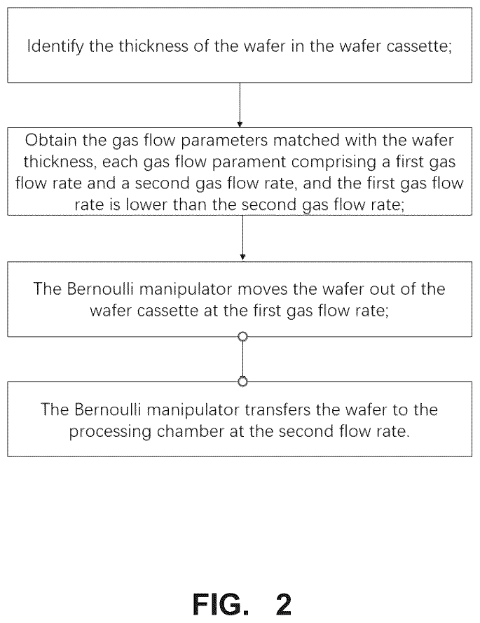

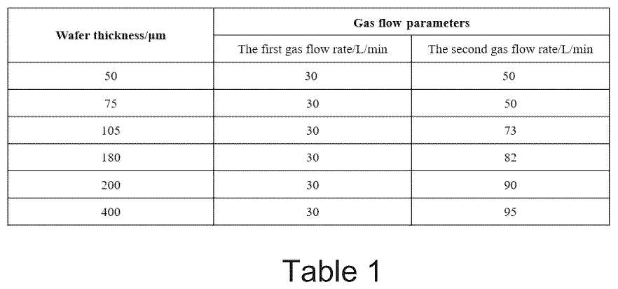

FIG. 2 shows a flowchart of the wafer transfer method according to an embodiment of the present invention. The transfer method of thin wafer is mainly used for Bernoulli manipulator to transfer thin wafer between a wafer cassette and a processing chamber. The Bernoulli manipulator is equipped with a gas path, which is used to provide gas to the Bernoulli manipulator. Specifically, the gas path adjusts the gas flow rate provided to the Bernoulli manipulator according to the thickness of the transferred thin wafer and the transferring stage of the wafer. The gas path of the Bernoulli manipulator will be introduced in detail later.

The specific steps of the transfer method of thin wafer will be described in detail with reference to FIG. 2.

Firstly, identify the thickness of the wafer in the wafer cassette. The wafer cassette provides an identification code, and the identification code has information about the thickness of the thin wafer in the wafer cassette. The thickness of the wafer is identified by reading the identification code on the wafer cassette. In an embodiment, the identification code can be a bar code with the thickness information of the wafer, which is determined by a code scanner or an identification sensor to identify the thickness of the wafer in the wafer cassette. In another embodiment, the identification code is a label suctioned on the wafer cassette, and the thickness of the wafer in the wafer cassette is filled in on the label. The operator can identify the wafer thickness in the wafer cassette according to the contents on the label.

Further, obtain the gas flow parameters matched with the wafer thickness, wherein each gas flow parameter includes a first gas flow rate and a second gas flow rate. The first gas flow rate is lower than the second gas flow rate. The first gas flow rate is the gas flow rate provided by the gas path to the Bernoulli manipulator in the process of moving the wafer from the wafer cassette, and the second gas flow rate is the gas flow rate provided to the Bernoulli manipulator by the gas path after the wafer moved from the wafer cassette and transferred to the processing chamber. Table 1 lists the gas flow parameters corresponding to some wafer thickness. For example, when the wafer thickness is 15 μm, the corresponding gas flow parameters should be: the first gas flow rate is 30 L/min, and the second gas flow rate is 73 L/min; When the wafer thickness is 200 μm, the corresponding gas flow parameters should be: the first gas flow rate is 30 L/min, and the second gas flow rate is 90 L/min. The table of gas flow parameters can be obtained according to experiments

Next, the gas path provides the gas with a first gas flow rate matching the thickness of the transferred wafer to the Bernoulli manipulator, and the Bernoulli manipulator moves the wafer out of the wafer cassette at the first gas flow rate.

After that, the gas path provides the gas with a second gas flow rate matching the thickness of the transferred wafer to the Bernoulli manipulator, and the Bernoulli manipulator transfers the wafer to the processing chamber at the second flow rate.

In one embodiment, the gas flow parameters are pre-stored in the controller of the wafer processing equipment. After receiving the identified wafer thickness, the controller automatically obtains the gas flow parameters matched with the identified wafer thickness, and then sends instructions to the gas path of the Bernoulli manipulator according to the obtained gas flow parameters, so that the gas path can provide corresponding gas flow rate to the Bernoulli manipulator at different transfer stages of the wafer.

In one embodiment, the processing chamber is a backside cleaning chamber. Before the Bernoulli manipulator transfers the wafer to the backside cleaning chamber, the Bernoulli manipulator flips to make the front side of the wafer facing down and the back side of the wafer facing up. Before the Bernoulli manipulator flips, the gas flow rate provided by the gas path to the Bernoulli manipulator increases from the first gas flow rate matched with the thickness of the transferred wafer to the second gas flow rate. When the Bernoulli manipulator adsorbs the wafer with the second gas flow rate, the suction force is large, which can avoid the wafer falling off the Bernoulli manipulator during and after the flipping process, causing debris.

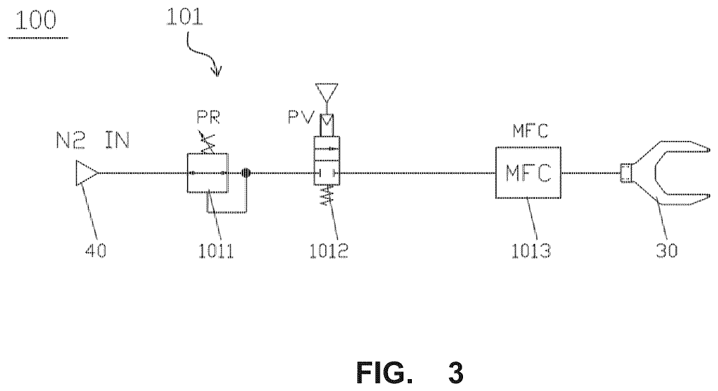

Referring to FIG. 3, a gas path 100 configured by a Bernoulli manipulator according to an embodiment of the present invention is disclosed. The gas path 100 comprises a main gas path 101, one end of the main gas path 101 is connected to the gas source 40, and the other end of the main gas path 101 in connected to the Bernoulli manipulator 30. A main flow regulating valve 1011, a main switch value 1012 and a main mass flow controller 1013 (MFC) are sequentially arranged on the main gas path 101 along the gas flow direction, and the main mass flow controller 1013 is used to adjust the gas flow rate in the main gas path 101. In this embodiment, the main mass flow controller 1013 adjusts the gas flow rate in the main gas path 101 according to the wafer thickness and the transfer stages of the wafer, so that the Bernoulli manipulator 30 can acquire the corresponding gas flow.

In actual operation, obtain gas flow parameters matched with the wafer thickness. For example, the wafer thickness stored in the wafer cassette is 180 μm, and the gas flow parameters corresponding to the wafer thickness can be obtained from Table 1: the first gas flow rate is 30 L/min, and the second gas flow rate is 82 L/min. Next, according to the obtained gas flow parameters, the main mass flow controller 1013 adjusts the gas flow in the main gas path 101 during the wafer moving from the wafer cassette, so that the main gas path 101 provides the gas which gas flow rate is 30 L/min for the Bernoulli manipulator. After the wafer moved from the wafer cassette, transferring to the processing chamber, the main mass flow controller 1013 adjusts the gas flow rate in the main gas path 101, so that the main gas path 101 provides the gas which gas flow is 82 L/min to the Bernoulli manipulator, which can not only prevent the wafer from chipping or cracking due to excessive suction force during the process of moving the wafer out of the wafer cassette, but also ensure that the Bernoulli manipulator has enough suction force to realize the stable transfer of the wafer to the processing chamber.

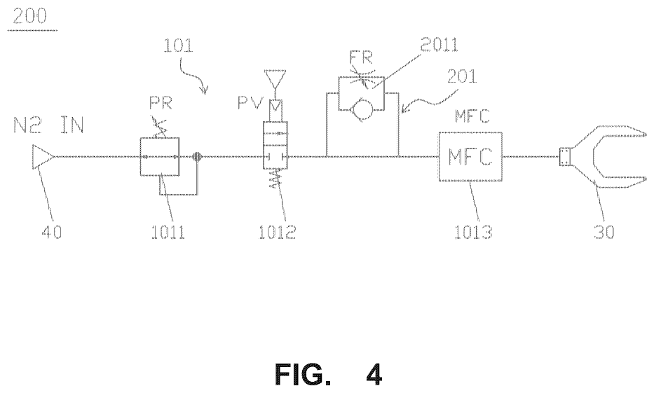

Referring to FIG. 4, a gas path 200 configured by a Bernoulli manipulator according to another embodiment of the present invention is disclosed. The gas path 200 comprises not only the main gas path 101, but also the branch gas path 201. One end of the branch gas path 201 is connected to the downstream side of the main switch value 1012, and the other end is connected to the upstream side of the main mass flow controller 1013. The branch gas path 201 is provided with a branch flow regulating valve 2011 for regulating the gas flow rate in the branch gas path 201. The main switch valve 2011 is used to regulate the gas flow rate in the branch gas path 201. The main switch valve 1012 is a three-way valve, and the gas flow path provided by the gas source 40 is switched between the main gas path 101 and the branch gas path 201 through the main switch valve 1012.

In actual operation, in the process of moving the wafer out of the wafer cassette, the Bernoulli manipulator 30 is supplied with gas flow rate that matching the thickness of the transferred wafer by the branch gas path 201, and the gas flow rate in the branch gas path 201 is regulated by the branch flow regulating valve 2011; In the process of transferring the wafer from the wafer cassette to the processing chamber, the second gas flow rate matching the thickness of the transferred wafer is provided to the Bernoulli manipulator by the main gas path 101, and the gas flow rate in the main gas path 101 is controlled by the main mass flow devices 1013.

Through experimental calculation, it is found that the first gas flow rates matched with different thickness thin wafer can be set to the same gas flow rate. As shown in Table 1, the gas flow rate in the branch gas path 201 does not need to be adjusted according to the thickness change of the wafer to be transferred. Therefore, the branch flow control valve 2011 provided in the branch gas path 201 can use a manual flow control valve to save costs.

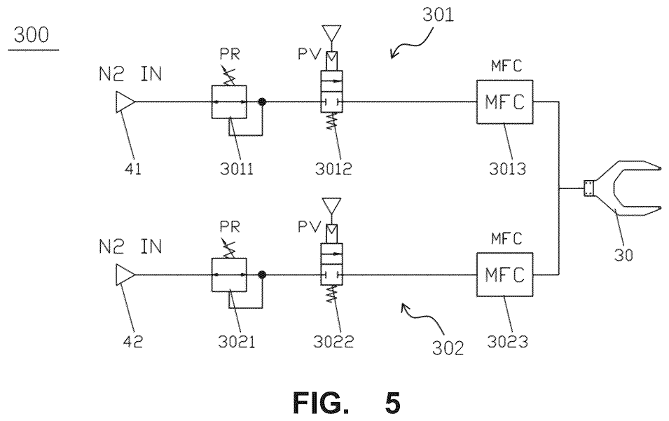

Referring to FIG. 5, a gas path 300 configured by a Bernoulli manipulator according to another embodiment of the present invention is disclosed. The gas path 300 comprises a first gas path 301 and a second gas path 302. One end of the first gas path 301 is connected to the gas source 41, and the other end is connected to the Bernoulli manipulator 30. A first flow regulating valve 3011, a first switch value 3012 and a first mass flow controller 3013 are sequentially arranged on the first gas path 301 along the gas flow direction, and the first mass flow controller 3013 is used for regulating the gas flow rate in the first gas path 301. One end of the second gas path 302 is connected to the gas source 42, and the other end is connected to the Bernoulli manipulator 30. A second flow regulating valve 3021, a second switch value 3022 and a second mass flow controller 3023 are sequentially arranged on the second gas path 302 along the gas flow direction, and the second mass flow controller 3023 is used for regulating the gas flow rate in the second gas path 302. In an embodiment, the gas source 41 and the gas source 42 can be the same gas source or two relatively independent gas sources.

In actual operation, in the process of moving the wafer out of the wafer cassette, the first gas path 301 provides the gas with the first gas flow rate to the Bernoulli manipulator 30 that matching the thickness of the transferred wafer; In the process of transferring the wafer from the wafer cassette to the processing chamber, the second gas flow rate matching the thickness of the transferred wafer is provided to the Bernoulli manipulator by the second gas path 302.

It should be noted that the mass flow controller is arranged at the bottom of various valves (switch valves, flow regulating valve) in the gas path in three gas paths 100,200,300 of the three Bernoulli manipulator configurations described above, near the Bernoulli manipulator. It can avoid the peak value of pressure or flow at the moment when the gas path is connected, so that the suction force of Bernoulli manipulator exceeds the threshold valuer and the wafer is chipped or cracked.

To sum up, the present invention has disclosed the relevant technologies in detail through the above-mentioned embodiments and related drawings, so that the technicians in this field can implement them accordingly. While that embodiment described above only use to illustrate the application, not to limit the application, and the scope of the rights of the application should be defined by the claims of the applications. As for the change of the number of elements or the substitution of equivalent elements described herein, it still belongs to the scope of the application.

What is claimed is:

1. A transfer method of thin wafer, for a Bernoulli manipulator with a gas path for providing gas to the Bernoulli manipulator to transfer thin wafer between a wafer cassette and a processing chamber, comprising the following steps:
identifying the thickness of the wafers in the wafer cassette;
obtaining gas flow parameters matched with the wafers' thickness, each gas flow parameter including two gas flow rates as a first gas flow rate and a second gas flow rate, the first gas flow rate being lower than the second gas flow rate;
providing the gas with the first gas flow rate matching the thickness of the transferred wafer to the Bernoulli manipulator through the gas path, the Bernoulli manipulator moving the wafer out of the wafer cassette at the first gas flow rate;
then, providing the gas with the second gas flow rate matching the thickness of the transferred wafer to the Bernoulli manipulator through the gas path, the Bernoulli manipulator transferring the wafer to the processing chamber at the second flow rate.

2. The transfer method of thin wafer according to claim 1, wherein the thickness of the thin wafer is 50 μm-400 μm.

3. The transfer method of thin wafer according to claim 1, wherein the gas path configured by the Bernoulli manipulator comprises a main gas path, one end of which connected to a gas source and the other end connected to the Bernoulli manipulator, the main gas path is configured with a main flow regulating valve, a main switch value and a main mass flow controller sequentially arranged along the gas flow direction, and the method comprises adjusting the gas flow rate in the main gas path through the main mass controller.

4. The transfer method of thin wafer according to claim 3, wherein, the main mass flow controller adjusts the gas flow rate in the main gas path in the process of moving the wafer out of the wafer cassette, so that the main gas path provides the gas with the first gas flow rate matching the thickness of the transferred wafer to the Bernoulli manipulator;
after the wafer being moved out of the wafer cassette and in the process of being transferred to the processing chamber, the main mass flow controller adjusts the gas flow rate in the main gas path, so that the main gas path provides the gas with the second gas flow rate matching the thickness of the transferred wafer to the Bernoulli manipulator.

5. The transfer method of thin wafer according to claim 3, wherein the gas path configured by the Bernoulli manipulator further comprises a branch gas path, one end of which connected to the downstream side of the main switch valve and the other end connected to the upstream side of the main mass flow controller, and the branch gas path is provided with a branch flow regulating valve for regulating the gas flow rate in the branch gas path.

6. The transfer method of thin wafer according to claim 5, wherein the branch gas path is used to provide the gas with the first gas flow rate matching the thickness of the transferred wafer to the Bernoulli manipulator during the process of moving the wafer out of the wafer cassette;
the main gas path is used to provide the gas with the second gas flow rate matching the thickness of the transferred wafer to the Bernoulli manipulator during the process of transferring the wafer which is moved out of the wafer cassette to the processing chamber.

7. The transfer method of thin wafer according to claim 1, wherein the gas path configured by the Bernoulli manipulator includes a first gas path and a second gas path;
one end of the first gas path is connected to a gas source, the other end is connected to the Bernoulli manipulator, the first gas path is sequentially set with a first flow regulating valve, a first switch value and a first mass flow controller along the gas flow direction, and the first mass flow controller is used for regulating the gas flow rate in the first gas path;
one end of the second gas path is connected to the gas source, the other end is connected to the Bernoulli manipulator, the second gas path is sequentially set with a second flow regulating valve, a second switch value and a second mass flow controller along the gas flow direction, and the second mass flow controller is used for regulating the gas flow rate in the second gas path.

8. The transfer method of thin wafer according to claim 7, wherein the first gas path is used to provide the gas with the first gas flow rate matching the thickness of the transferred wafer to the Bernoulli manipulator during the process of moving the wafer out of the wafer cassette;
the second gas path is used to provide the gas with the second gas flow rate matching the thickness of the transferred wafer to the Bernoulli manipulator during the process of transferring the wafer which is moved out of the wafer cassette to the processing chamber.

9. The transfer method of thin wafer according to claim 1, wherein the wafer cassette is provided with an identification code with wafer thickness information, and the method identifies the thickness of wafers in the wafer cassette by reading the identification code on the wafer cassette.

10. The transfer method of thin wafer according to claim 1, wherein the processing chamber is a backside cleaning chamber, before the wafer is transferred to the backside cleaning chamber by the Bernoulli manipulator, the Bernoulli manipulator flips to make the front side of the wafer facing down and the back side of the wafer facing up; before the Bernoulli manipulator flips, the gas flow rate provided by the gas path to the Bernoulli manipulator increases from the first gas flow rate matching the thickness of the transferred wafer to the second gas flow rate.
